(19) United States
(12) Patent Application Publication
(10) Pub. No.: US 2024/0014154 A1
(43) Pub. Date: Jan. 11, 2024

(54) SEMICONDUCTOR DEVICE WITH PAD STRUCTURE RESISTANT TO PLASMA DAMAGE AND MANUFACTURING METHOD THEREOF

(71) Applicant: Richtek Technology Corporation, Hsinchu (TW)

(72) Inventors: Wu-Te WENG, Hsinchu (TW); Yong-Zhong HU, Hsinchu (TW)

(21) Appl. No.: 18/186,974

(22) Filed: Mar. 21, 2023

(30) Foreign Application Priority Data
Jul. 5, 2022 (TW) 111125197

(51) Int. Cl. H01L 23/00

(52) U.S. Cl. CPC H01L 24/05; H01L 24/02; H01L 24/03; H01L 2224/02381; H01L 2224/05548; H01L 2224/05567; H01L 2224/05124; H01L 2224/05147; H01L 2224/05624; H01L 2224/0239; H01L 2924/01013; H01L 2224/05085; H01L 2224/03462; H01L 2224/0391

(57) ABSTRACT

A semiconductor device with a pad structure resistant to plasma damage includes: a main pad portion including main conductor units and main via units; a sub-pad portion including sub-conductor units and sub-via units; a pad bonding unit in direct contact with and in connection with a top main conductor unit, wherein the top main conductor unit is the main conductor unit formed in a top metal layer; and a bridge pad unit in direct contact with a top sub-conductor unit, wherein the top sub-conductor unit is the sub-conductor unit formed in the top metal layer. The bridge pad unit is in direct contact with the pad bonding unit. The main pad portion and sub-pad portion are located below the pad bonding unit and bridge pad unit respectively, and the main pad portion and the sub-pad portion are not in direct connection with each other.

### CROSS REFERENCE

The present invention claims priority to TW 111125197 filed on Jul. 5, 2022.

### BACKGROUND OF THE INVENTION

### Field of Invention

The present invention relates to a semiconductor device with pad structure resistant to plasma damage and a manufacturing method thereof; particularly, it relates to such semiconductor device with pad structure resistant to plasma damage, wherein its main pad portion and its sub-pad portion are connected only via a pad bonding unit and a bridge pad unit, and a manufacturing method thereof.

### Description of Related Art

Please refer to FIG. 1, which shows a cross-section view of a pad structure of a conventional semiconductor device. As shown in FIG. 1, in the pad structure of this conventional semiconductor device, each of mental layers M13, M23, M33, M43, and each via unit Via4 connecting the mental layers M13, M23, M33, M43, and each dielectric layer, all contribute serious plasma damage effect (or referred to as “antenna effect”) to a gate of each metal oxide semiconductor (MOS) device located below the above-mentioned layers. As a consequence, the gate of the MOS device located below can be easily punched through and damaged.

In view of the above, to overcome the drawback in the prior art, the present invention proposes a semiconductor device with pad structure resistant to plasma damage and a manufacturing method thereof, which are capable of effectively reducing the plasma damage effect.

### SUMMARY OF THE INVENTION

From one perspective, the present invention provides a semiconductor device with the pad structure resistant to plasma damage, comprising: a main pad portion including a plurality of main conductor units formed in a plurality of corresponding metal layers and a plurality of main via units formed in a plurality of corresponding dielectric layers, wherein the metal layers include a top metal layer, and wherein the plurality of main via units are electrically connected to the plurality of corresponding main conductor units, so that the plurality of main conductor units are electrically connected with one another; a sub-pad portion including a plurality of sub-conductor units formed in the plurality of corresponding metal layers and a plurality of sub-via units formed in the plurality of corresponding dielectric layers, wherein the plurality of sub-via units are electrically connected to the plurality of corresponding sub-conductor units, so that the plurality of sub-conductor units are electrically connected with one another and so that the sub-pad portion is electrically connected to a gate of at least one metal oxide semiconductor (MOS); a pad bonding unit, which is in direct contact with and is in connection with a top main conductor unit, wherein the top main conductor unit is the main conductor unit formed in the top metal layer; and a bridge pad unit, which is in direct contact with and is in connection with a top sub-conductor unit, wherein the top sub-conductor unit is the sub-conductor unit formed in the top metal layer; wherein the bridge pad unit is in direct contact with and in connection with the pad bonding unit; wherein the main pad portion and the sub-pad portion are located below the pad bonding unit and the bridge pad unit, respectively, and the main pad portion and the sub-pad portion are not in direct connection with each other.

From another perspective, the present invention provides a manufacturing method of a semiconductor device with the pad structure resistant to plasma damage, comprising steps of: forming a main pad portion and a sub-pad portion via a patterning process step, wherein the main pad portion includes: a plurality of main conductor units formed in a plurality of corresponding metal layers and a plurality of main via units formed in a plurality of corresponding dielectric layers, wherein the metal layers include a top metal layer, and wherein the plurality of main via units are electrically connected to the plurality of corresponding main conductor units, so that the plurality of main conductor units are electrically connected with one another; wherein the sub-pad portion includes: a plurality of sub-conductor units formed in the plurality of corresponding metal layers and a plurality of sub-via units formed in the plurality of corresponding dielectric layers, wherein the plurality of sub-via units are electrically connected to the plurality of corresponding sub-conductor units, so that the plurality of sub-conductor units are electrically connected with one another and so that the sub-pad portion is electrically connected to a gate of at least one metal oxide semiconductor (MOS); forming a pad bonding unit, so that the pad bonding unit is in direct contact with and is in connection with a top main conductor unit, wherein the top main conductor unit is the main conductor unit formed in the top metal layer; and forming bridge pad unit, so that the bridge pad unit is in direct contact with and is in connection with a top sub-conductor unit, wherein the top sub-conductor unit is the sub-conductor unit formed in the top metal layer; wherein the bridge pad unit is in direct contact with and in connection with the pad bonding unit; wherein the main pad portion and the sub-pad portion are located below the pad bonding unit and the bridge pad unit, respectively, and the main pad portion and the sub-pad portion are not in direct connection with each other.

In one embodiment, each of the sub-conductor units encircles a corresponding one of the main conductor units which is formed in a same metal layer.

In one embodiment, each of the sub-conductor units does not encircle a corresponding one of the main conductor units which is formed in a same metal layer, but each of the sub-conductor units is located outside of the corresponding main conductor unit which is formed in the same metal layer, wherein each of the sub-conductor units has a dot structure.

In one embodiment, a surface area of each of the main conductor units is greater than a surface area of each of the sub-conductor units.

In one embodiment, a ratio of a surface area of each of the sub-conductor units to a surface area of the gate is lower than a ratio defined in a predetermined antenna design rule.

In one embodiment, the pad bonding unit and the bridge pad unit are formed in a redistribution layer (RDL) which is on the main pad portion and the sub-pad portion, wherein the RDL is in direct contact with the top metal layer.

In one embodiment, the plurality of main conductor units and the plurality of sub-conductor units include a material of copper (Cu) or aluminum (Al).

In one embodiment, the pad bonding unit and the bridge pad unit include a material of aluminum (Al).

In one embodiment, the pad bonding unit and the bridge pad unit are formed by an electrodeposition process step.

According to the present invention, a pad bonding unit and a bridge pad unit are formed via an electrodeposition process step, so that a main pad portion and a sub-pad portion are connected only via the pad bonding unit and the bridge pad unit, to significantly reduce plasma damage.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-section view of a pad structure of a conventional semiconductor device.

FIG. 2 shows a cross-section view of a semiconductor device with a pad structure resistant to plasma damage according to an embodiment of the present invention.

FIG. 3 shows a top view of a semiconductor device with a pad structure resistant to plasma damage according to an embodiment of the present invention.

FIG. 4 shows a top view of a semiconductor device with a pad structure resistant to plasma damage according to another embodiment of the present invention.

FIG. 5A to FIG. 5Q show a cross-section view of a manufacturing method of a semiconductor device with a pad structure resistant to plasma damage according to an embodiment of the present invention.

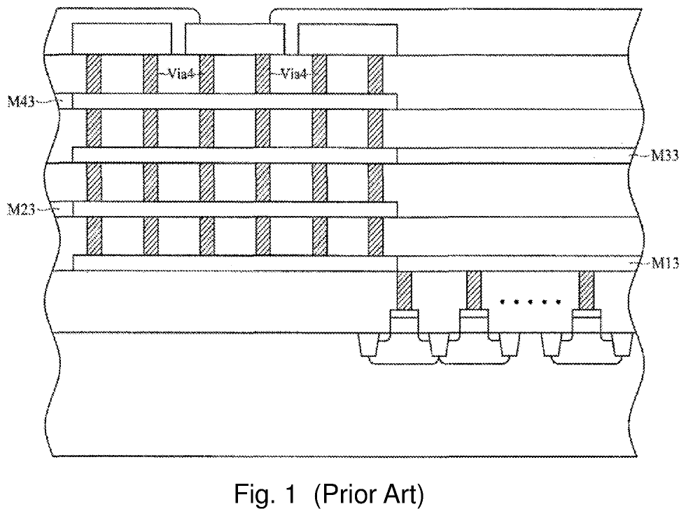

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

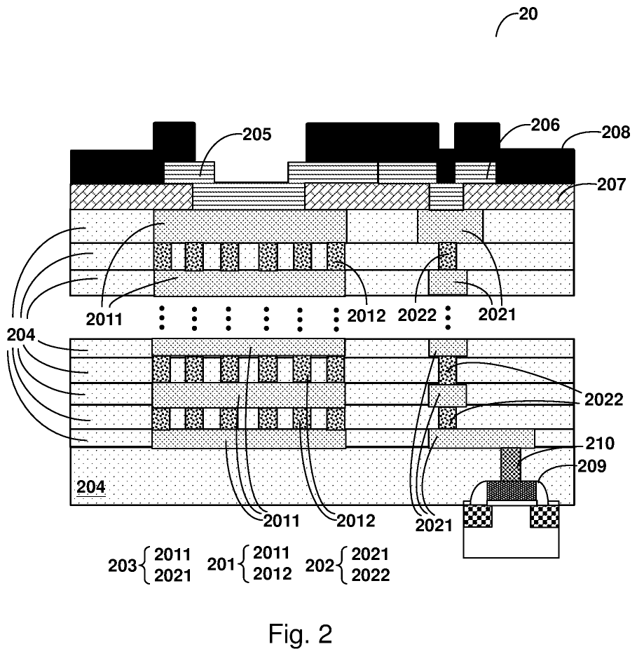

FIG. 2 shows a cross-section view of a semiconductor device with a pad structure resistant to plasma damage according to an embodiment of the present invention. As shown in FIG. 2, the semiconductor device 20 with the pad structure resistant to plasma damage of the present invention includes: a main pad portion 201, a sub-pad portion 202, a pad bonding unit 205 and a bridge pad unit 206. The main pad portion 201 includes: main conductor units 2011 which are formed in corresponding metal layers 203 and main via units 2012 which are formed in corresponding dielectric layers 204. The main via units 2012 are electrically connected to the corresponding main conductor units 2011, so that the main conductor units 2011 are electrically connected with one another. The sub-pad portion 202 includes: sub-conductor units 2021 which are formed in the corresponding metal layers 203 and sub-via units 2022 which are formed in the corresponding dielectric layers 204. The sub-via units 2022 are electrically connected to the corresponding sub-conductor units 2021, so that the sub-conductor units 2021 are electrically connected with one another. The sub-pad portion 202 is electrically connected to a gate 209 of at least one metal oxide semiconductor (MOS) device through, for example, a conductive plug 210.

The pad bonding unit 205 is in direct contact with and is in connection with a top main conductor unit, wherein the top main conductor unit is the main conductor unit 2011 which is formed in a top metal layer 203. The bridge pad unit 206 is in direct contact with and is in connection with a top sub-conductor unit, wherein the top sub-conductor unit is the sub-conductor unit 2021 which is formed in the top metal layer 203. The bridge pad unit 206 is in direct contact with and in connection with the pad bonding unit 205. The main pad portion 201 and the sub-pad portion 202 are located below the pad bonding unit 205 and the bridge pad unit 206, respectively, and the main pad portion 201 and the sub-pad portion 202 are not in direct connection with each other. A passivation layer 207 is formed on a top surface of the dielectric layer 204, wherein a part of the passivation layer 207 is formed on a part of the top main conductor unit and a part of the passivation layer 207 is formed on a part of the top sub-conductor unit. Optionally, a polymer layer 208 can be formed on the passivation layer 207. And, a part of the polymer layer 208 is formed on a part of the pad bonding unit 205 and the bridge pad unit 206. As shown in FIG. 2, the size of an opening in the passivation layer 207 on the main pad portion 201 is greater than the size of an opening in the passivation layer 207 on the sub-pad portion 202, so that the plasma generated at the sub-pad portion 202 has a relatively lower density, whereby an object to be test (e.g., the gate 209 of the MOS device) connected to the sub-pad portion 202 will suffer a relatively milder plasma damage.

In one embodiment, the surface area of each of the main conductor units 2011 is greater than the surface area of each of the sub-conductor units 2021. In one embodiment, a ratio of the surface area of the sub-conductor units 2021 to the surface area of the gate 209 is lower than a ratio defined in a predetermined antenna design rule (predetermined antenna ratio). In one embodiment, the pad bonding unit 205 and the bridge pad unit 206 are formed in a redistribution layer (RDL) which is on the main pad portion 201 and the sub-pad portion 202, wherein the RDL is in direct contact with the top metal layer 203. In one embodiment, the main conductor units 2011 and the sub-conductor units 2021 include a material of, for example but not limited to, copper (Cu) or aluminum (Al). In one embodiment, the pad bonding unit 205 and the bridge pad unit 206 include a material of, for example but not limited to, aluminum (Al).

The predetermined antenna ratio is thus. During manufacturing the semiconductor device, if a gate of a MOS device in the semiconductor substrate and a portion of the pad structure are electrically connected in a manufacturing process step, the predetermined antenna ratio limits an area ratio of the portion of the pad structure (which forms an antenna) to the gate in such corresponding process steps, so as to avoid excessive plasma damage on the gate.

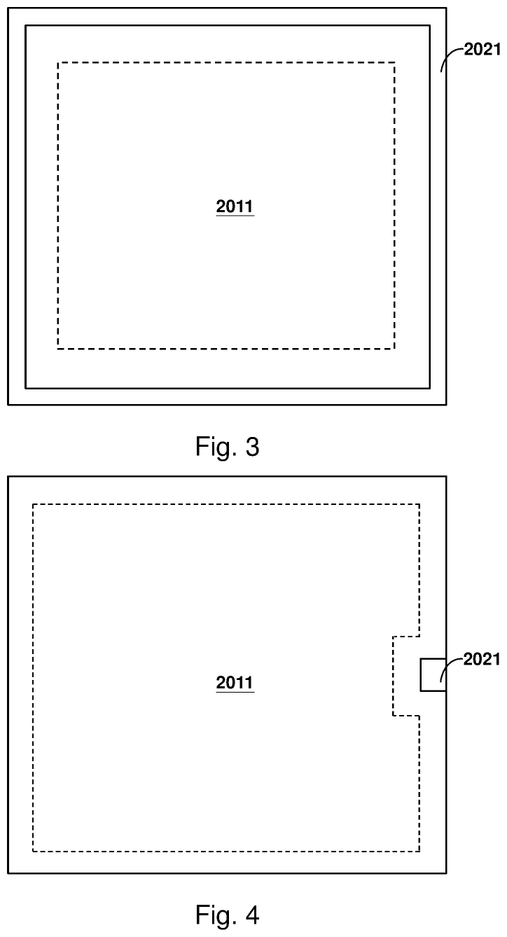

FIG. 3 shows a top view of a semiconductor device with a pad structure resistant to plasma damage according to an embodiment of the present invention. In one embodiment, as shown in FIG. 3, the sub-conductor unit 2021 encircles the corresponding main conductor unit 2011 which is formed in the same metal layer 203. FIG. 4 shows a top view of a semiconductor device with a pad structure resistant to plasma damage according to another embodiment of the present invention. In another embodiment, as shown in FIG. 4, the sub-conductor unit 2021 does not encircle the corresponding main conductor unit 2011 which is formed in the same metal layer 203; the sub-conductor unit 2021 is located outside of the corresponding main conductor unit 2011 which is formed in the same metal layer 203, wherein the sub-conductor unit 2021 has a dot structure.

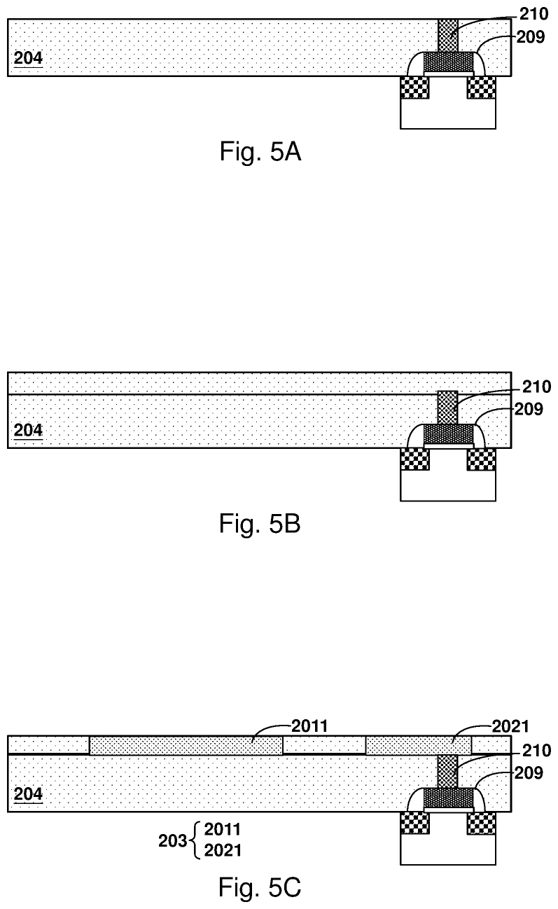

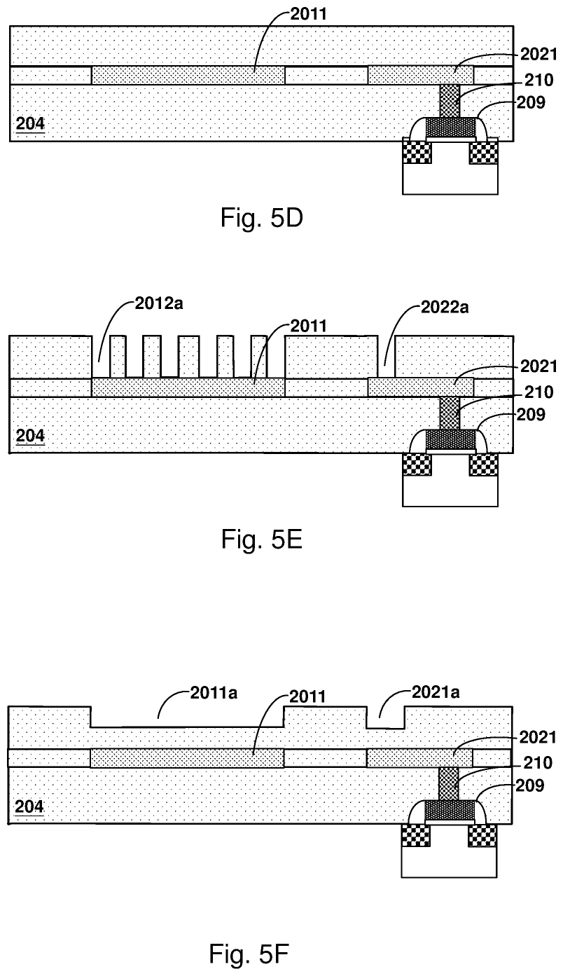

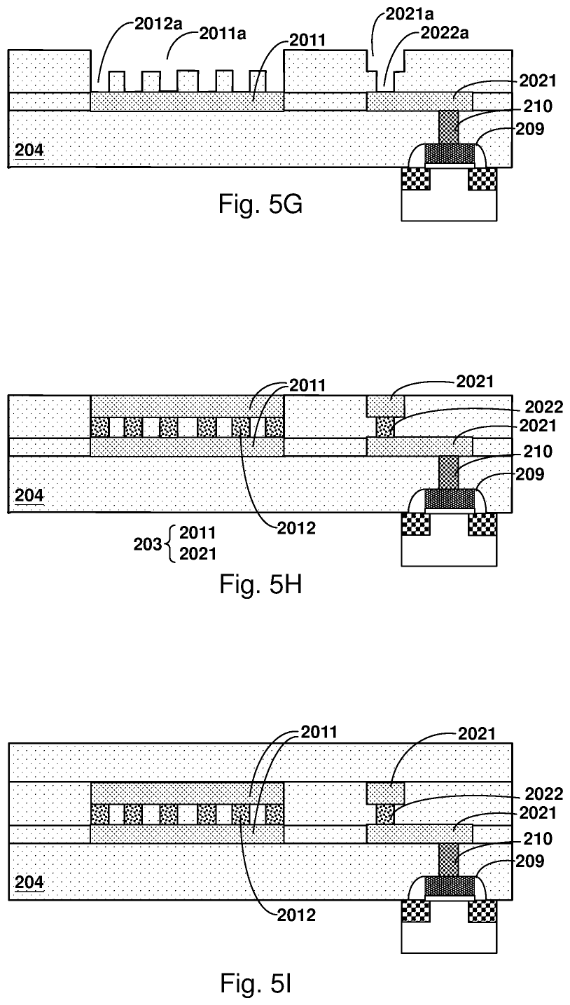

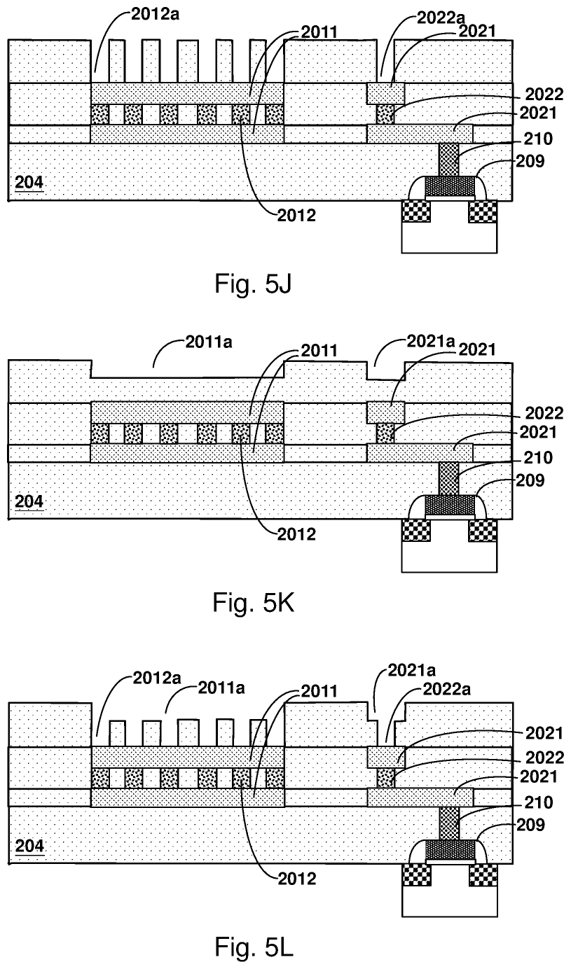

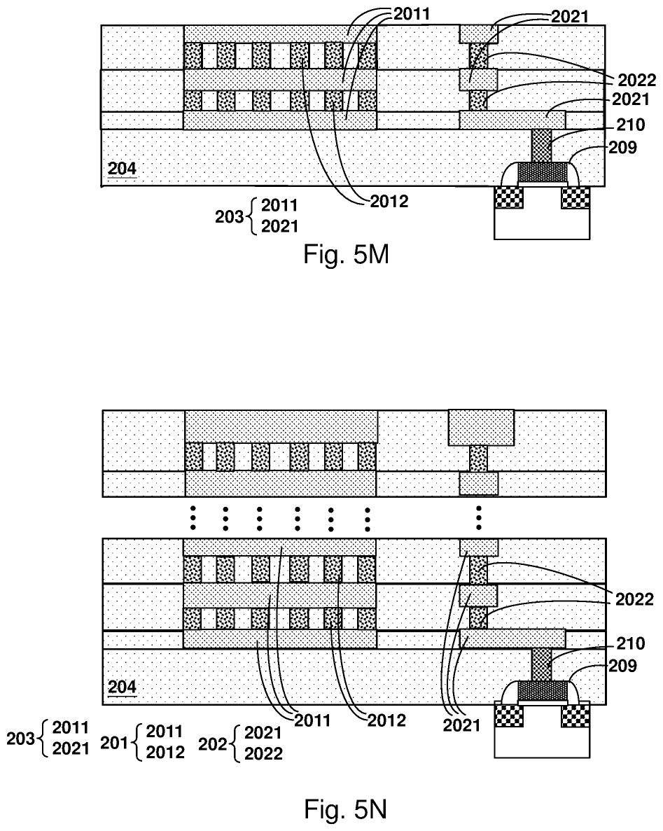

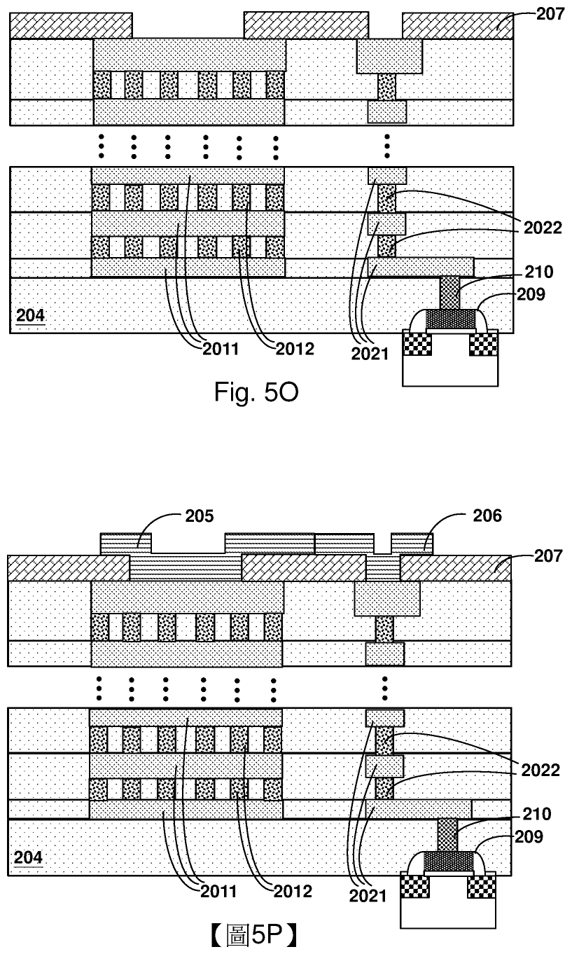

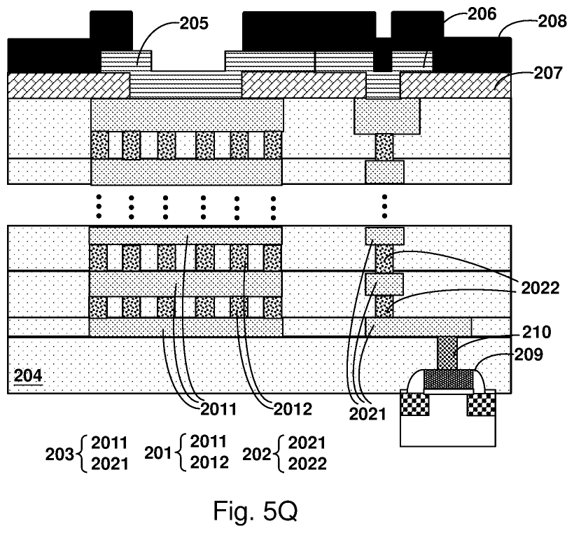

FIG. 5A to FIG. 5Q show cross-section views of a manufacturing method of a semiconductor device with a pad structure resistant to plasma damage according to an embodiment of the present invention. First, as shown in FIG. 5A, a MOS device is formed, and a dielectric layer 204 is formed by for example a deposition process step. Besides, a conductive plug 210 is formed by, for example but not limited to, a lithography process step, an etching step and a deposition process step, and the formed conductive plug 210 is coupled to the gate 209 of the MOS device. Next, referring to FIG. 5B, another dielectric layer 204 is formed by for example the deposition process step. Next, referring to FIG. 5C, a main conductor unit 2021 are formed in a metal layer 203 by a patterning process step, wherein the patterning process step includes, for example but not limited to, a lithography process step and an etching step, and a deposition process step or an electrodeposition process step. Next, referring to FIG. 5D, another dielectric layer 204 is formed by for example the deposition process step.

Next, referring to FIG. 5E, in one embodiment, first, narrow through-holes 2012a for accommodating the main via units and a narrow through-hole 2022a for accommodating the sub-via unit are formed by a patterning process step, wherein the patterning process step includes, for example but not limited to, a lithography process step and an etching step (one narrow through-hole 2022a and one sub-via unit are illustrated in the figure; however there can be plural narrow through-holes 2022a and plural sub-via units). Next, referring to FIG. 5G, a broad through-hole 2011a for accommodating the main conductor unit and a broad through-hole 2021a for accommodating the sub-conductor unit are formed by a patterning process step, wherein the patterning process step includes, for example but not limited to, a lithography process step and an etching step (one broad through-hole 2011a and one broad through-hole 2021a are illustrated in the figure; however there can be plural broad through-holes 2011a and plural broad through-holes 2021a). Or, in one alternative embodiment, as shown in FIG. 5F, first, a broad through-hole 2011a for accommodating a main conductor unit and a broad through-hole 2021a for accommodating a sub-conductor unit are formed by a patterning process step, wherein the patterning process step includes, for example but not limited to, a lithography process step and an etching step (one broad through-hole 2011a and one broad through-hole 2021a are illustrated in the figure; however there can be plural broad through-holes 2011a and plural broad through-holes 2021a). Subsequently, narrow through-holes 2012a for accommodating main via units and a narrow through-hole 2022a for accommodating a sub-via unit are formed by a patterning process step, wherein the patterning process step includes, for example but not limited to, a lithography process step and an etching step (one narrow through-hole 2022a and one sub-via unit are illustrated in the figure; however there can be plural narrow through-holes 2022a and plural sub-via units).

Next, referring to FIG. 5H, the main via units 2012 and the sub-via unit 2022 are formed in the narrow through-holes 2012a and the narrow through-hole 2022a by a deposition process step. And, a main conductor unit 2011 and a sub-conductor unit 2021 are formed in the broad through-holes 2011a and the broad through-holes 2021 by a deposition process step or an electrodeposition process step, so as to form the main conductor units 2011 and the sub-conductor units 2021 in the metal layer 203, and, for example but not limited to, a chemical mechanical polishing process step is performed, to form the main via units 2012 and the sub-via unit 2022 in the dielectric layer 204. Next, referring to FIG. 5I, another dielectric layer 204 is formed by for example the deposition process step.

Next, referring to FIG. 5J, first, narrow through-holes 2012a for accommodating main via units and a narrow through-hole 2022a for accommodating a sub-via unit are formed by a patterning process step, wherein the patterning process step includes, for example but not limited to, a lithography process step and an etching step. Next, referring to FIG. 5L, a broad through-hole 2011a for accommodating a main conductor unit and a broad through-hole 2021a for accommodating a sub-conductor unit are formed by a patterning process step, wherein the patterning process step includes, for example but not limited to, a lithography process step and an etching step. Or, in one alternative embodiment, as shown in FIG. 5K, a broad through-hole 2011a for accommodating a main conductor unit and a broad through-hole 2021a for accommodating a sub-conductor unit are formed by a patterning process step, wherein the patterning process step includes, for example but not limited to, a lithography process step and an etching step. Subsequently, narrow through-holes 2012a for accommodating main via units and a narrow through-hole 2022a for accommodating a sub-via unit are formed by a patterning process step, wherein the patterning process step includes, for example but not limited to, a lithography process step and an etching step.

Next, referring to FIG. 5M, the main via units 2012 and the sub-via unit 2022 are formed in the narrow through-holes 2012a and the narrow through-hole 2022a by a deposition process step. And, a main conductor unit 2011 and a sub-conductor unit 2021 are formed in the broad through-holes 2011a and the broad through-holes 2021 by a deposition process step or an electrodeposition process step, so as to form the main conductor units 2011 and the sub-conductor units 2021 in the metal layer 203, and, for example but not limited to, a chemical mechanical polishing process step is performed, to form the main via units 2012 and the sub-via unit 2022 in the dielectric layer 204.

Next, the steps shown in FIG. 5I to FIG. 5M are repeated, and next, referring to FIG. 5N, a main pad portion 201 and a sub-pad portion 202 are formed. The main pad portion 201 includes: main conductor units 2011 formed in corresponding metal layers 203 and main via units 2012 formed in corresponding dielectric layers 204. The main via units 2012 are electrically connected to the corresponding main conductor units 2011, so that the main conductor units 2011 are electrically connected with one another. The sub-pad portion 202 includes: sub-conductor units 2021 formed in the metal layers 203 and sub-via units 2022 formed in the dielectric layers 204. The sub-via units 2022 are electrically connected to the corresponding sub-conductor units 2021, so that the sub-conductor units 2021 are electrically connected to one another. The sub-pad portion 202 is electrically connected to a gate 209 of at least one metal oxide semiconductor (MOS) device through, for example, a conductive plug 210.

Next, referring to FIG. 5O, a passivation layer 207 is formed on a top surface of the dielectric layer 204, wherein a part of the passivation layer 207 is formed on a part of the top main conductor unit and a part of the passivation layer 207 is formed on a part of the top sub-conductor unit, by, for example but not limited to, a deposition process step. Next, referring to FIG. 5P, a pad bonding unit 205 is formed on the passivation layer 207, wherein the pad bonding unit 205 is formed on a part of the top main conductor unit, and a bridge pad unit 206 is formed on the passivation layer 207 and the bridge pad unit 206 is formed on a part of the top sub-conductor unit. The pad bonding unit 205 is in direct contact with and is in connection with a top main conductor unit, wherein the top main conductor unit is the main conductor unit 2011 which is formed in a top metal layer 203. Besides, the bridge pad unit 206 is in direct contact with and is in connection with a top sub-conductor unit, wherein the top sub-conductor unit is the sub-conductor unit 2021 which is formed in the top metal layer 203.

The bridge pad unit 206 is in direct contact with and in connection with the pad bonding unit 205. The main pad portion 201 and the sub-pad portion 202 are located below the pad bonding unit 205 and the bridge pad unit 206, respectively, and the main pad portion 201 and the sub-pad portion 202 are not in direct connection with each other. In one embodiment, the pad bonding unit 205 and the bridge pad unit 206 are formed in a redistribution layer (RDL) which is on the main pad portion 201 and the sub-pad portion 202, wherein the RDL is in direct connection with the top metal layer 203. In one embodiment, the main conductor units 2011 and the sub-conductor units 2021 include a material of, for example but not limited to, copper (Cu) or aluminum (Al). In one embodiment, the pad bonding unit 205 and the bridge pad unit 206 include a material of, for example but not limited to, aluminum (Al). In one embodiment, the pad bonding unit 205 and the bridge pad unit 206 are formed by, for example but not limited to, an electrodeposition process step and a lithography process step, so that the main pad portion 201 and the sub-pad portion 202 are connected only via the pad bonding unit 205 and the bridge pad unit 206, whereby the plasma damage can be significantly reduced.

Next, referring to FIG. 5Q, optionally, a polymer layer 208 is formed on the passivation layer 207 by, for example but not limited to, a deposition process step, wherein a part of the polymer layer 208 is formed on a part of the pad bonding unit 205 and the bridge pad unit 206.

As described above, the present invention forms the pad bonding unit 205 and the bridge pad unit 206 by, for example but not limited to, an electrodeposition process step, so that the main pad portion 201 and the sub-pad portion 202 are connected only via the pad bonding unit 205 and the bridge pad unit 206, thus significantly reducing plasma damage.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a light doping drain (LDD) region, may be added. For another example, the lithography process step is not limited to the mask technology but it can also include electron beam lithography. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A semiconductor device with a pad structure resistant to plasma damage, comprising:
a main pad portion including a plurality of main conductor units formed in a plurality of corresponding metal layers and a plurality of main via units formed in a plurality of corresponding dielectric layers, wherein the metal layers include a top metal layer, and wherein the plurality of main via units are electrically connected to the plurality of corresponding main conductor units, so that the plurality of main conductor units are electrically connected with one another;
a sub-pad portion including a plurality of sub-conductor units formed in the plurality of corresponding metal layers and a plurality of sub-via units formed in the plurality of corresponding dielectric layers, wherein the plurality of sub-via units are electrically connected to the plurality of corresponding sub-conductor units, so that the plurality of sub-conductor units are electrically connected with one another and so that the sub-pad portion is electrically connected to a gate of at least one metal oxide semiconductor (MOS);
a pad bonding unit, which is in direct contact with and is in connection with a top main conductor unit, wherein the top main conductor unit is the main conductor unit formed in the top metal layer; and
a bridge pad unit, which is in direct contact with and is in connection with a top sub-conductor unit, wherein the top sub-conductor unit is the sub-conductor unit formed in the top metal layer;
wherein the bridge pad unit is in direct contact with and in connection with the pad bonding unit;
wherein the main pad portion and the sub-pad portion are located below the pad bonding unit and the bridge pad unit, respectively, and the main pad portion and the sub-pad portion are not in direct connection with each other.

2. The semiconductor device with a pad structure resistant to plasma damage of claim 1, wherein each of the sub-conductor units encircles a corresponding one of the main conductor units which is formed in a same metal layer.

3. The semiconductor device with a pad structure resistant to plasma damage of claim 1, wherein each of the sub-conductor units does not encircle a corresponding one of the main conductor units which is formed in a same metal layer, but each of the sub-conductor units is located outside of the corresponding main conductor unit which is formed in the same metal layer, wherein each of the sub-conductor units has a dot structure.

4. The semiconductor device with a pad structure resistant to plasma damage of claim 1, wherein a surface area of each of the main conductor units is greater than a surface area of each of the sub-conductor units.

5. The semiconductor device with a pad structure resistant to plasma damage of claim 1, wherein a ratio of a surface area of each of the sub-conductor units to a surface area of the gate is lower than a ratio defined in a predetermined antenna design rule.

6. The semiconductor device with a pad structure resistant to plasma damage of claim 1, wherein the pad bonding unit and the bridge pad unit are formed in a redistribution layer (RDL) which is on the main pad portion and the sub-pad portion, wherein the RDL is in direct contact with the top metal layer.

7. The semiconductor device with a pad structure resistant to plasma damage of claim 1, wherein the plurality of main conductor units and the plurality of sub-conductor units include a material of copper (Cu) or aluminum (Al).

8. The semiconductor device with a pad structure resistant to plasma damage of claim 1, wherein the pad bonding unit and the bridge pad unit include a material of aluminum (Al).

9. The semiconductor device with a pad structure resistant to plasma damage of claim 1, wherein the pad bonding unit and the bridge pad unit are formed by an electrodeposition process step.

10. A manufacturing method of a semiconductor device with a pad structure resistant to plasma damage, comprising steps of:
forming a main pad portion and a sub-pad portion via a patterning process step, wherein the main pad portion includes: a plurality of main conductor units formed in a plurality of corresponding metal layers and a plurality of main via units formed in a plurality of corresponding dielectric layers, wherein the metal layers include a top metal layer, and wherein the plurality of main via units are electrically connected to the plurality of corresponding main conductor units, so that the plurality of main conductor units are electrically connected with one another; wherein the sub-pad portion includes: a plurality of sub-conductor units formed in the plurality of corresponding metal layers and a plurality of sub-via units formed in the plurality of corresponding dielectric layers, wherein the plurality of sub-via units are electrically connected to the plurality of corresponding sub-conductor units, so that the plurality of sub-conductor units are electrically connected with one another and so that the sub-pad portion is electrically connected to a gate of at least one metal oxide semiconductor (MOS);
forming a pad bonding unit, so that the pad bonding unit is in direct contact with and is in connection with a top main conductor unit, wherein the top main conductor unit is the main conductor unit formed in the top metal layer; and
forming bridge pad unit, so that the bridge pad unit is in direct contact with and is in connection with a top sub-conductor unit, wherein the top sub-conductor unit is the sub-conductor unit formed in the top metal layer;
wherein the bridge pad unit is in direct contact with and in connection with the pad bonding unit;
wherein the main pad portion and the sub-pad portion are located below the pad bonding unit and the bridge pad unit, respectively, and the main pad portion and the sub-pad portion are not in direct connection with each other.

11. The manufacturing method of claim 10, wherein each of the sub-conductor units encircles a corresponding one of the main conductor units which is formed in a same metal layer.

12. The manufacturing method of claim 10, wherein each of the sub-conductor units does not encircle a corresponding one of the main conductor units which is formed in a same metal layer, but each of the sub-conductor units is located outside of the corresponding main conductor unit which is formed in the same metal layer, wherein each of the sub-conductor units has a dot structure.

13. The manufacturing method of claim 10, wherein a surface area of each of the main conductor units is greater than a surface area of each of the sub-conductor units.

14. The manufacturing method of claim 10, wherein a ratio of a surface area of each of the sub-conductor units to a surface area of the gate is lower than a ratio defined in a predetermined antenna design rule.

15. The manufacturing method of claim 10, wherein the pad bonding unit and the bridge pad unit are formed in a redistribution layer (RDL) which is on the main pad portion and the sub-pad portion, wherein the RDL is in direct contact with the top metal layer.

16. The manufacturing method of claim 10, wherein the plurality of main conductor units and the plurality of sub-conductor units include a material of copper (Cu) or aluminum (Al).

17. The manufacturing method of claim 10, wherein the pad bonding unit and the bridge pad unit include a material of aluminum (Al).

18. The manufacturing method of claim 10, wherein the pad bonding unit and the bridge pad unit are formed by an electrodeposition process step.
